(19) United States
(12) Patent Application Publication
(10) Pub. No.: US 2012/0074368 A1
(43) Pub. Date: Mar. 29, 2012

(54) SEMICONDUCTOR MEMORY DEVICE AND MANUFACTURING METHOD THEREOF

(75) Inventors: Yoshitaka SASAGO, Tachikawa (JP); Masaharu KINOSHITA, Kokubunji (JP); Mitsuharu TAI, Kokubunji (JP); Akio SHIMA, Hino (JP); Takashi KOBAYASHI, Higashimurayama (JP)

(73) Assignee: HITACHI, LTD.

(21) Appl. No.: 13/181,663

(22) Filed: Jul. 13, 2011

(30) Foreign Application Priority Data
Sep. 27, 2010 (JP) 2010-214665

(51) Int. Cl. H01L 47/00; H01L 21/3205

(52) U.S. Cl. 257/2; 438/587; 257/E47.001; 257/E21.294

(57) ABSTRACT

A semiconductor memory device having a diode and a transistor connected in series, which prevents carriers from going from the diode into the transistor, thereby reducing the possibility of transistor deterioration. A structure to annihilate carriers from the diode is provided between a channel layer of the transistor and a diode semiconductor layer of the diode where the carriers are generated.

### CLAIM OF PRIORITY

The present application claims priority from Japanese patent application JP 2010-214665 filed on Sep. 27, 2010, the content of which is hereby incorporated by reference into this application.

### FIELD OF THE INVENTION

The present invention relates to semiconductor memory devices.

### BACKGROUND OF THE INVENTION

In recent years, studies on phase-change random access memories which use chalcogenide as a recording material have been extensively conducted (Japanese Unexamined Patent Application Publication No. 2004-272975 and Japanese Unexamined Patent Application Publication No. 2005-260014). The memory structure of a phase-change random access memory is that a recording material is placed between metal electrodes. The phase-change random access memory is a resistance-change memory which stores data by taking advantage of the fact that the recording material between electrodes has different resistance states.

The phase-change random access memory stores data by taking advantage of the fact that the resistance of a phase-change material such as Ge₂Sb₂Te₅ is different between its amorphous state and crystalline state. Its resistance is high in the amorphous state and low in the crystalline state. Reading is done by giving a potential difference to both ends of the element and measuring the current flowing in the element to decide whether the element is in a high resistance state or low resistance state.

In the phase-change random access memory, data is rewritten by changing the electric resistance of the phase-change film to a different level using the Joule heat generated by the current. Resetting, namely operation to change the material to a high-resistance amorphous state, is done by applying a large current for a short time to melt the phase-change material, then decreasing the current rapidly. On the other hand, setting, namely operation to change the material to a low-resistance crystalline state, is done by applying a sufficient current to keep the phase-change material at the crystallization temperature for a long time. Theoretically phase-change random access memories are suitable for miniaturization because the current required to change the state of the phase-change film becomes smaller as miniaturization progresses. For this reason, studies on phase-change random access memories have been extensively conducted.

As an approach to realizing a highly integrated memory which uses such resistance-change element, Japanese Unexamined Patent Application Publication No. 2008-160004 discloses a technique where plural through holes are made at a time in such a way as to penetrate a laminated structure having plural gate electrode material layers and plural insulating films alternately stacked and a gate insulating film, a channel layer and a phase-change film are deposited inside the through holes and processed.

### SUMMARY OF THE INVENTION

The phase-change random access memory described in Japanese Unexamined Patent Application Publication No. 2008-160004 has the problem that a chain selection device for selecting a vertical chain memory is a vertical transistor and a plurality of such chain selection transistors are provided for one source line and these chain selection transistors must be independently selectable. Consequently, gate electrodes must be isolated by an insulating film, which produces gaps in the source line direction and thus hinders the improvement in the degree of integration.

If a vertical diode is used in place of a vertical transistor, the structure can be simplified and the degree of integration can be increased. A 2-terminal device, the diode is structurally simple, so the manufacturing process is simpler and the manufacturing cost is lower than the transistor. As a consequence, the cost per bit can be much lower than when the vertical transistor is used as a chain selection device.

However, if a vertical diode is used as a chain selection device, the cell transistor which constitutes a chain memory must be connected in series with the vertical diode as a selection device. When a forward bias voltage is applied to the diode to apply a current to the chain memory and activate it, minority carriers may diffuse from the diode into the cell transistor channel. If minority carriers get into the cell transistor channel, there is concern that the off-state characteristics of the cell transistor may deteriorate, causing reading or writing errors.

An object of the present invention is to prevent the diffusion of minority carriers from a diode in a vertical transistor and improve the reliability of a semiconductor memory which uses a diode as a chain selection device.

The above and further objects and novel features of the invention will more fully appear from the following detailed description in this specification and the accompanying drawings.

Preferred embodiments of the invention which will be disclosed herein are briefly outlined below.

According to one aspect of the invention, there is provided a semiconductor memory device which includes: a first selection line provided over a semiconductor substrate; a first diode semiconductor layer which is electrically connected with the first selection line and is of first conductivity type; a second diode semiconductor layer which is electrically connected with the first diode semiconductor layer and is of second conductivity type different from the first conductivity type; a plurality of gate semiconductor layers stacked through a plurality of insulating layers over the semiconductor substrate; a gate insulating film layer provided along lateral sides of the gate semiconductor layers; a channel layer which is provided on a lateral side of the gate insulating film layer where the gate semiconductor layers are not provided and is electrically connected with the second diode semiconductor layer; and a second selection line which is electrically connected with the channel layer and extends perpendicularly to the first selection line. In the semiconductor memory device, a means to annihilate carriers of the first conductivity type lies between the first diode semiconductor layer and the channel layer.

According to a second aspect of the invention, there is provided a semiconductor memory device which includes: a first selection line provided over a semiconductor substrate; a first diode semiconductor layer which is electrically connected with the first selection line and is of first conductivity type; a second diode semiconductor layer which is electrically connected with the first diode semiconductor layer and is of second conductivity type different from the first conductivity type; a plurality of gate semiconductor layers stacked through a plurality of insulating layers over the semiconductor substrate; a gate insulating film layer provided along lateral sides of the gate semiconductor layers; a channel layer which is provided on a lateral side of the gate insulating film layer where the gate semiconductor layers are not provided and is electrically connected with the second diode semiconductor layer; and a second selection line which is electrically connected with the channel layer and extends perpendicularly to the first selection line.

When the device is in operation, a current not more than one hundredth of the current flowing in a diode including the first diode semiconductor layer and the second diode semiconductor layer, flows from the diode to the channel layer.

According to a third aspect of the invention, there is provided a method for manufacturing a semiconductor memory device which includes the steps of: forming a first selection line on a semiconductor substrate; forming a first diode semiconductor layer of first conductivity on the first selection line; forming, over the first diode semiconductor layer, a second diode semiconductor layer of second conductivity type different from the first conductivity type; forming, over the first diode semiconductor layer, a means to annihilate carriers of the first conductivity type; forming, over the semiconductor substrate, a plurality of gate semiconductor layers stacked through a plurality of insulating layers; forming a gate insulating layer along lateral sides of the gate semiconductor layers; and forming a channel layer along a lateral side of the gate insulating layer where the gate semiconductor layers are not provided.

According to the present invention, it is possible to provide an inexpensive highly reliable semiconductor memory device.

### BRIEF DESCRIPTION OF THE DRAWINGS

FIG. 1 illustrates the problem with the use of a diode for a chain selection device;

FIG. 2 illustrates deterioration in the off-state characteristics of a cell transistor due to minority carriers (holes);

FIG. 3 illustrates the relation between minority carrier current (hole current) and off-state characteristics;

FIG. 4 is a fragmentary sectional view of a semiconductor memory device according to a first embodiment of the invention;

FIG. 5 is a fragmentary perspective view showing the semiconductor memory device according to the first embodiment;

FIG. 6 is a perspective view showing a memory cell array according to the first embodiment;

FIG. 7 is a graph showing change in the resistance of a phase-change random access memory from high to low;

FIG. 8 illustrates resetting, setting and reading operations of the memory cell array;

FIG. 9 illustrates resetting, setting and reading operations of the memory cell array;

FIG. 10 is a schematic perspective view showing a step in the method for manufacturing a semiconductor memory device according to the first embodiment;

FIG. 11 is a schematic perspective view showing a step in the method for manufacturing a semiconductor memory device according to the first embodiment;

FIG. 12 is a schematic perspective view showing a step in the method for manufacturing a semiconductor memory device according to the first embodiment;

FIG. 13 is a schematic perspective view showing a step in the method for manufacturing a semiconductor memory device according to the first embodiment;

FIG. 14 is a schematic perspective view showing a step in the method for manufacturing a semiconductor memory device according to the first embodiment;

FIG. 15 is a schematic perspective view showing a step in the method for manufacturing a semiconductor memory device according to the first embodiment;

FIG. 16 is a schematic perspective view showing a step in the method for manufacturing a semiconductor memory device according to the first embodiment;

FIG. 17 is a schematic perspective view showing a step in the method for manufacturing a semiconductor memory device according to the first embodiment;

FIG. 18 is a schematic perspective view showing a step in the method for manufacturing a semiconductor memory device according to the first embodiment;

FIG. 19 is a schematic perspective view showing a step in the method for manufacturing a semiconductor memory device according to the first embodiment;

FIG. 20 is a schematic perspective view showing a step in the method for manufacturing a semiconductor memory device according to the first embodiment;

FIG. 21 is a schematic perspective view showing a step in the method for manufacturing a semiconductor memory device according to the first embodiment;

FIG. 22 is a schematic perspective view showing a step in the method for manufacturing a semiconductor memory device according to the first embodiment;

FIG. 23 is a schematic perspective view showing a step in the method for manufacturing a semiconductor memory device according to the first embodiment;

FIG. 24 is a schematic perspective view showing a step in the method for manufacturing a semiconductor memory device according to the first embodiment;

FIG. 25 is a schematic perspective view showing a step in the method for manufacturing a semiconductor memory device according to the first embodiment;

FIG. 26 is a schematic perspective view showing a step in the method for manufacturing a semiconductor memory device according to the first embodiment;

FIG. 27A is a fragmentary enlarged view illustrating the step shown in FIG. 25 and FIG. 27B is a fragmentary enlarged view illustrating the step shown in FIG. 26;

FIG. 28 is a sectional view illustrating a step in the method for manufacturing a semiconductor memory device according to the first embodiment;

FIG. 29 is a sectional view illustrating a step in the method for manufacturing a semiconductor memory device according to the first embodiment;

FIG. 30 is a schematic perspective view showing a step in the method for manufacturing a semiconductor memory device according to a second embodiment of the invention;

FIG. 31 is a schematic perspective view showing a step in the method for manufacturing a semiconductor memory device according to a third embodiment of the invention;

FIG. 32 is a schematic perspective view showing a step in the method for manufacturing a semiconductor memory device according to a fifth embodiment of the invention;

FIG. 33 is a schematic perspective view showing a semiconductor memory device according to a sixth embodiment of the invention; and

FIG. 34 is a sectional view of the semiconductor memory device according to the sixth embodiment, taken along a bit line.

### DETAILED DESCRIPTION OF THE PREFERRED EMBODIMENTS

Next, the preferred embodiments of the present invention will be described in detail referring to the accompanying drawings. In all the drawings that illustrate the preferred embodiments, elements with like functions are designated by like reference numerals and repeated descriptions of such elements are omitted. It should be noted that the characteristic aspects of the invention described herein are not limited to the preferred embodiments but other embodiments which have the same aspects can bring about the same effects.

### First Embodiment

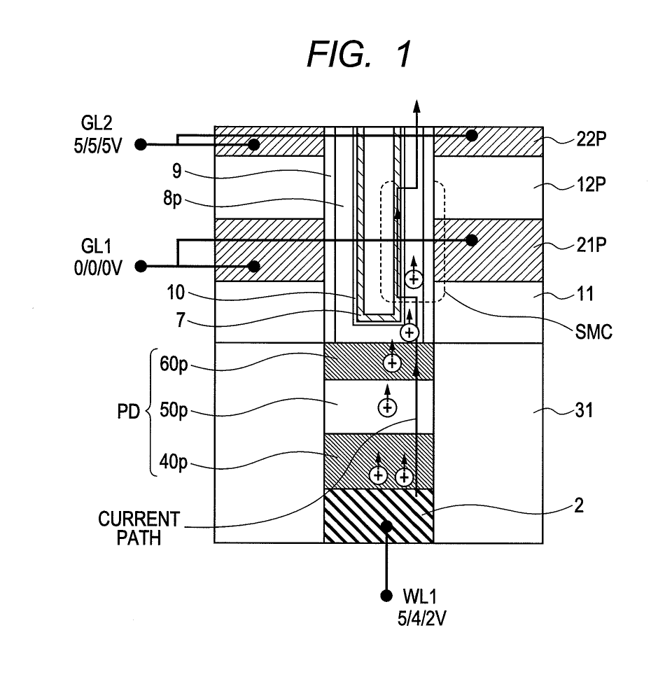

Prior to discussing the present invention, the present inventors investigated the problem of the technique which uses a diode as a chain selection device. FIG. 1 is a schematic diagram showing a device in which a transistor is connected in series over a diode PD including a p-type polysilicon layer 40p containing holes, a polysilicon 50p layer with a low concentration of impurities, and an n-type polysilicon layer 60p. When a forward bias voltage is applied to the diode PD to apply a current, holes from the p-type polysilicon layer 40p flow into the n-type polysilicon layer 60p through the polysilicon layer 50p containing impurities at a low concentration.

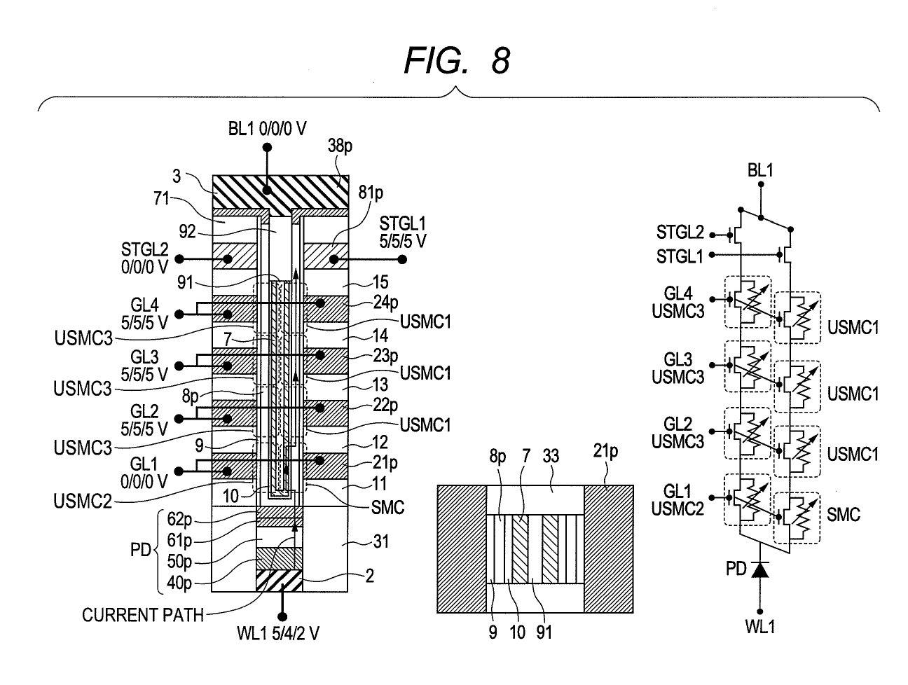

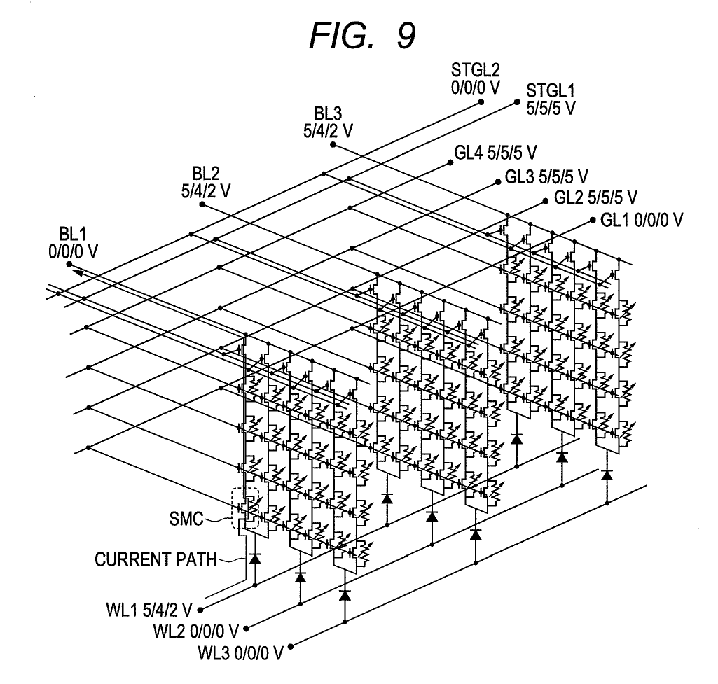

Since the n-type polysilicon layer has a high concentration of electrons, many of the holes flowing into it combine with electrons and are annihilated. However, holes which do not combine with electrons pass through the n-type polysilicon layer 60p and these holes flow into the channel polysilicon layer 8p of an NMOS transistor. As the holes flow into the channel of the NMOS transistor, the threshold lowers and the off-state electron current increases rapidly. In the chain memory according to the first embodiment, by turning the transistor of the selection cell SMC to its off state during operation, current is applied to the phase-change material of SMC to activate it, as will be stated later in reference to FIGS. 8 and 9. Therefore, if there is a large flow of holes into the channel polysilicon layer 8p, the chain cell transistor cannot be turned off, making reading and setting/resetting impossible.

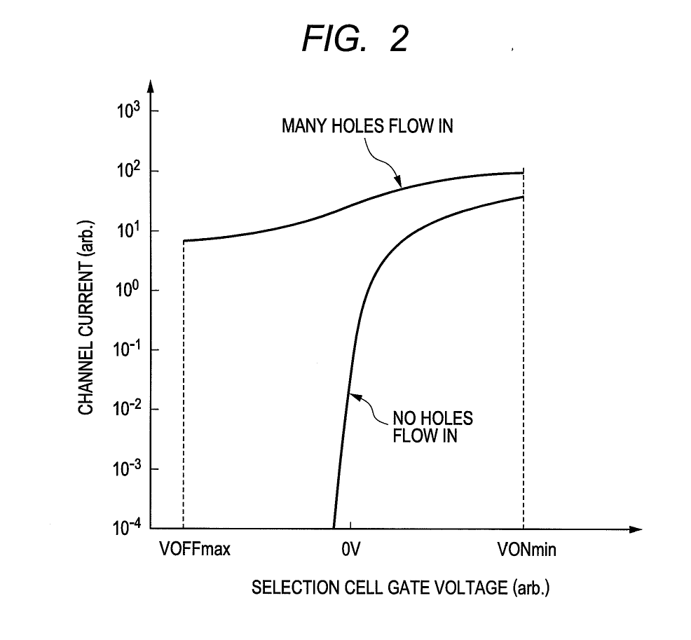

FIG. 2 compares the transistor characteristics in the case of no holes flowing into the channel polysilicon 8p and those in the case of many holes flowing into it. In the absence of a flow of holes into it, the transistor can turn off normally and there is virtually no leak current at the maximum off-state voltage VOFFMAX. On the other hand, when many holes flow into it, the transistor cannot be turned off.

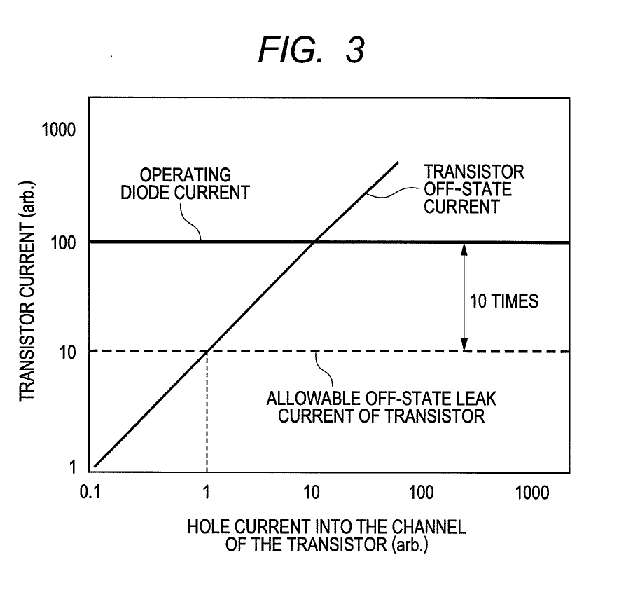

FIG. 3 illustrates the relation between minority carrier current (hole current) and off-state characteristics. Assuming the current of the diode in operation as 100, the allowable off-state current of the transistor is approximately one tenth of it (namely about 10). The transistor's off-state current caused by the hole current into the channel of the transistor is approximately ten times as much as the hole current into the channel of the transistor. Therefore, if a means to reduce the hole current into the channel of the transistor to 1, equivalent to one hundredth of the current of the diode in operation, exists between the p-type polysilicon layer 40p and the channel layer 8p, the transistor can be turned off normally.

Based on the above findings, the technique disclosed herein is a carrier annihilating structure which is provided between the channel layer and the diode PD's semiconductor layer where carriers are generated (p-type polysilicon layer 40p in this embodiment). In other words, disclosed herein is a structure in which not more than one hundredth of the current flowing in the diode PD flows from the diode into the channel layer. This structure permits the transistor to turn off normally, so a vertical diode can be used as a chain selection device, offering the advantageous effects of a higher degree of integration and a lower manufacturing process cost. This feature is the same as in the second and subsequent embodiments which will be discussed later.

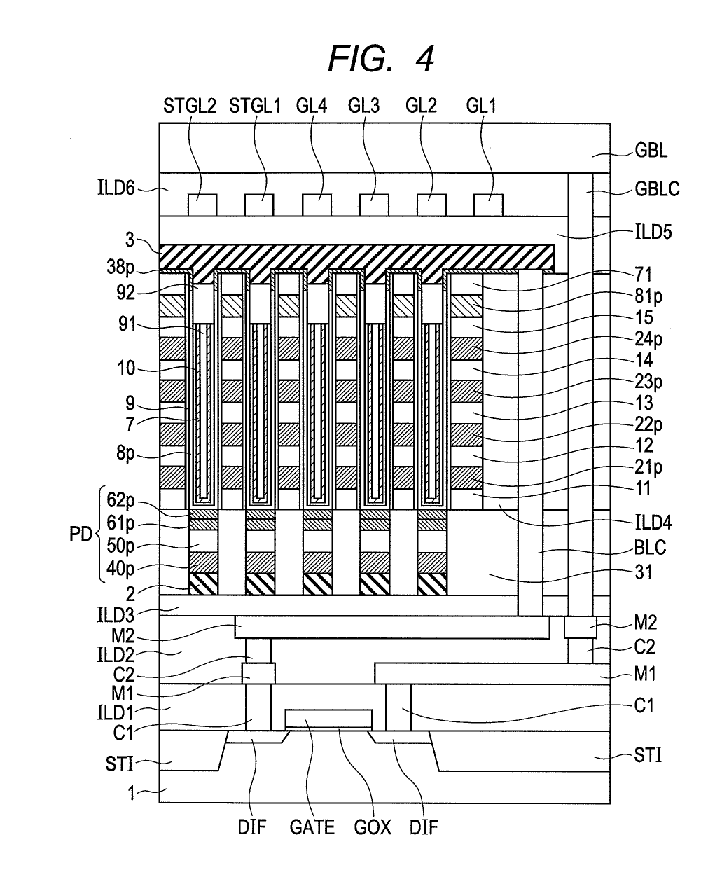

FIG. 4 is a fragmentary sectional view of a semiconductor memory device according to the first embodiment of the invention partially showing a memory cell array, interconnect wires, and contacts. As shown in FIG. 4, the device includes: a device isolation trench STI formed in a semiconductor substrate 1; a transistor's gate GATE, gate insulating film GOX, diffusion layer DIF, interlayer insulating films ILD1, ILD2, ILD3, ILD4, ILD5, and ILD6, interconnection layers M1 and M2; contact holes C1 for connecting the device on the semiconductor substrate and M1; contact holes C2 for connecting M1 and M2; word lines 2 as metal wires; a polysilicon diode PD including a polysilicon layer 40p doped with p-type impurities, a polysilicon layer 50p doped with a low concentration of impurities, and polysilicon layers 61p and 62p doped with n-type impurities; gate polysilicon layers 21p, 22p, 23p, 24p and 81p; a gate insulating film 9; channel polysilicon 8p; a phase-change material film 7; an upper diffusion layer portion 38p; metal wires GL1, GL2, GL3, GL4, STGL1, and STGL2 for power supply to the gate polysilicon; bit lines 3; a contact hole BLC for connecting the bit lines 3 and the circuit formed on the semiconductor substrate 1; an insulating film layer 11 between the polysilicon diode PD and the gate polysilicon layer 21p; insulating film layers 12, 13, 14, and 15 between gate polysilicon layers; and an insulating film 71 between the gate polysilicon layer 81p and the diffusion layer 38p.

In other words, the semiconductor memory device according to the first embodiment includes: first selection lines (word lines 2) provided over the semiconductor substrate; a first diode semiconductor layer (polysilicon layer 40p) of the first conductivity type (for example, p-type) which is connected with the first selection lines electrically; a second diode semiconductor layer (60p) which is connected with the first diode semiconductor layer electrically and is of the second conductivity type (for example, n type), different from the first conductivity type; plural gate semiconductor layers (21p to 24p) which are stacked through plural insulating layers (12 to 15) over the semiconductor substrate; a gate insulating film layer (9) provided along lateral sides of the gate semiconductor layers; a channel layer (8p) provided on a lateral side of the gate insulating film layer where the gate semiconductor layers are not provided and is electrically connected with a third semiconductor layer; and second selection lines (bit lines 3) electrically connected with the channel layer, extending perpendicularly to the first selection lines.

In addition, the semiconductor device is characterized by having semiconductor layers of the second conductivity type stacked in order to annihilate carriers of the first conductivity type or make the current flowing from the diode into the channel layer not more than one hundredth of the current flowing in the diode PD. FIG. 4 illustrates the polysilicon layer doped with n-type impurities as a constituent of the diode which is comprised of two layers 61p and 62p. When a forward bias voltage is applied to the diode to apply a current, holes from the polysilicon layer doped with p-type impurities are trapped in the boundary between 61p and 62p and combined (annihilated) with electrons so that diffusion of holes into the channel 8p of the overlying vertical transistor can be reduced.

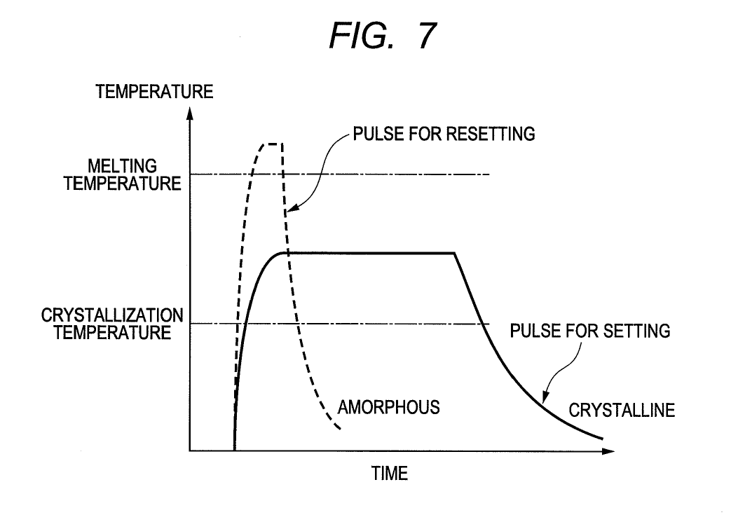

Furthermore, as shown in FIG. 4, a phase-change material layer (7) is provided along the lateral side of the gate insulating film where the gate semiconductor layers are not provided, and is connected with the third diode semiconductor layer and the second selection lines electrically. The material of this layer is a material whose resistance changes depending on the current flowing therein (which will be explained later in reference to FIG. 7). Thanks to the presence of this layer, a phase-change random access memory suitable for miniaturization can be realized.

As shown in FIG. 4, the device further includes a third diode semiconductor layer (polysilicon layer 50p) provided between the first diode semiconductor layer and the second diode semiconductor layer and electrically connected with the first diode semiconductor layer and the second diode semiconductor layer. The impurity concentration of this third diode semiconductor layer is lower than those of the first and second diode semiconductor layers. The third diode semiconductor layer is not essential and as far as the device includes at least the first and second diode semiconductor layers, the diode PD can function as a selection element. However, the presence of the third diode semiconductor layer makes it possible to widen the depletion layer in the electric field direction and weaken the depletion layer field when a reverse bias voltage is applied to the diode. By doing so, the withstand voltage in the reverse bias direction can be increased. As will be explained later in reference to FIG. 9, more preferable array operation can be achieved by making the withstand voltage in the reverse bias direction sufficiently large.

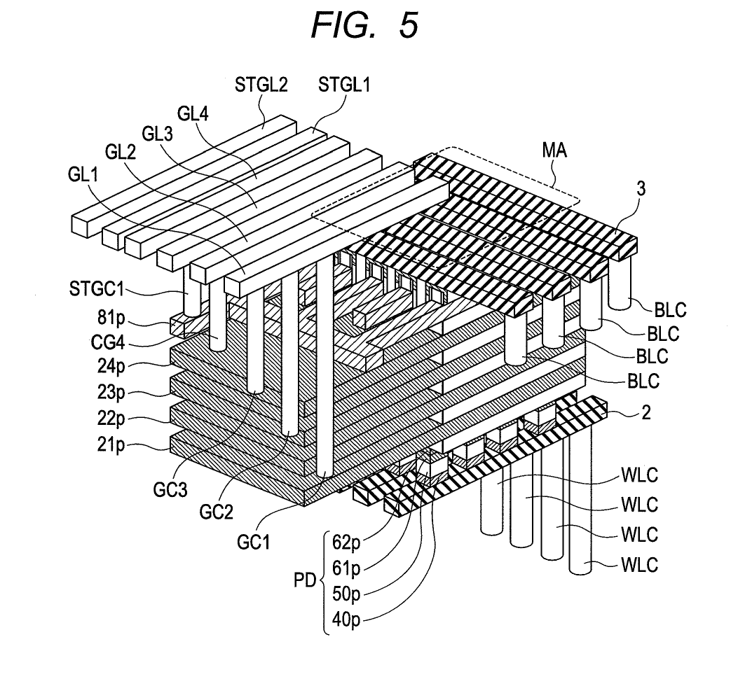

FIG. 5 is a fragmentary schematic perspective view showing the semiconductor memory device according to the first embodiment. The memory cell array, interconnect wires and contacts are partially shown in FIG. 5. As shown in FIG. 5, the device includes; word lines 2 as metal wires; contact holes WLC for connecting the word lines 2 and the peripheral circuit; a polysilicon diode PD including a polysilicon layer 40p doped with p-type impurities, a polysilicon layer 50p doped with a low concentration of impurities, and polysilicon layers 61p and 62p doped with n-type impurities; memory cell gate polysilicon layers 21p, 22p, 23p, and 24p; a selection transistor gate polysilicon layer 81p; metal wires GL1, GL2, GL3, and GL4 for power supply to the memory cell gate polysilicon layers; metal wires STGL1 and STGL2 for power supply to the selection transistor gate polysilicon layer 81p; contacts GC1, GC2, GC3, and GC4 for connecting the memory cell gate polysilicon layers 21p, 22p, 23p and 24p and the wires GL1, GL2, GL3, and GL4 respectively; a contact STGC1 for connecting the selection transistor gate polysilicon layer 81p and the wire STGL1; bit lines 3; contacts BLC for connecting the bit lines 3 and the circuit on the semiconductor substrate 1; an insulating film layer 11 between the polysilicon diode PD and the gate polysilicon layer 21p; insulating film layers 12, 13, 14, and 15 between gate polysilicon layers; and an insulating film 71 between the gate polysilicon layer 81p and the diffusion layer 38p.

Though not shown, the wires GL1, GL2, GL3, and GL4 are connected through GLC1, GLC2, GLC3, and GLC4 to the peripheral circuit formed on the semiconductor substrate 1 respectively. Also the wires STGL1 and STGL2 are connected through STGLC1 and STGLC2 to the peripheral circuit respectively. The gate polysilicon layers 21p, 22p, 23p, 24p, and 81p are illustrated as being alternately connected in common. Details are as follows.

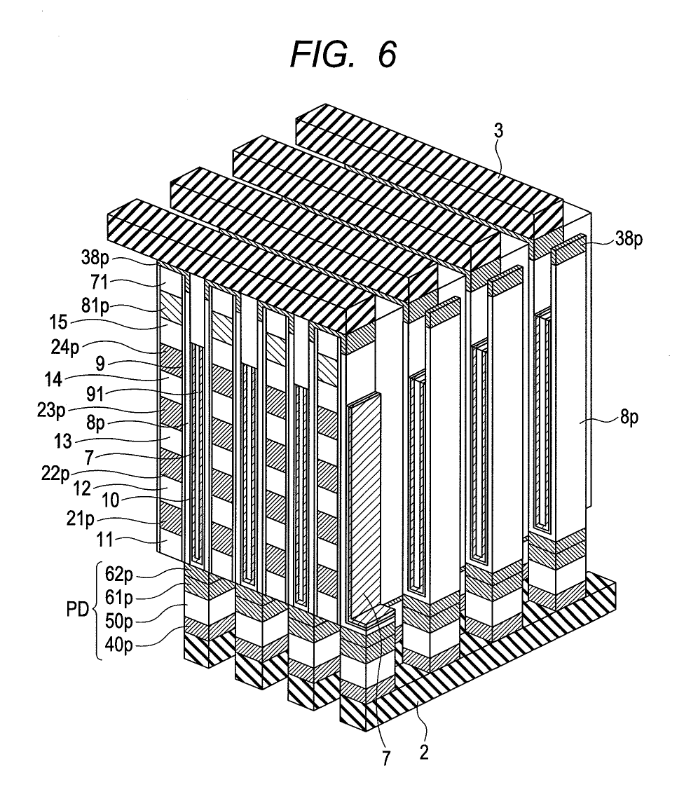

The gate polysilicon layers 21p, 22p, 23p, 24p, and 81p are each formed so as to make a pattern of stripes on a plane in the memory array MA (which will be explained later in reference to FIG. 6). Among these gate polysilicon layers 21p, 22p, 23p, 24p, and 81p, the odd-numbered ones are short-circuited on the front side as seen in FIG. 5 and commonly interconnected.

On the other hand, referring to FIG. 5, the even-numbered ones among the gate polysilicon layers 21p, 22p, 23p, 24p, and 81p look isolated without being connected with other wires. However, though the corresponding stripe patterns are not shown in FIG. 5, they are connected similarly on the opposite side in the direction of the word lines of the memory array MA.

In addition, the gate polysilicon layers 21p, 22p, 23p, 24p, and 81p are connected through the contacts GC1, GC2, GC3, GC4, and STGC2 to the gate lines GL1, GL2, GL3, GL4, and STGL2 respectively. In FIG. 5, only the odd-numbered gate polysilicon layers appear to be connected through contacts to the gate lines on the front side of the memory array MA. However, though not shown in FIG. 5, the even-numbered ones are also connected through contacts to the gate lines on the opposite side of the memory array MA in the same way as the odd-numbered ones.

Therefore, in the memory cell gate polysilicon layer 21p, whether the neighboring stripes are odd-numbered or even-numbered, they are all connected to the same wire GL1 and short-circuited with each other. Consequently, when a given potential is applied to GL1, the whole gate polysilicon layer 21p comes to have the same potential as the applied potential. In other words, all the cells in the same plane as the gate polysilicon layer 21p can be collectively selected or deselected. The same is true for the gate polysilicon layers 22p, 23p, and 24p. Therefore, due to this connection relationship, selection cells/non-selection cells can be determined in the z axis direction (height direction) in the memory array MA as will be explained later.

On the other hand, in the gate polysilicon layer 81p, the odd-numbered lines (stripes) and the even-numbered ones are not connected to the same wire. Specifically, the odd-numbered lines are connected to the wire STGL1 and the even-numbered ones are connected to STGL2, namely the stripes are alternately connected to the two mutually isolated wires STGL1 and STGL2 and a voltage can be applied to each of them independently. Due to this connection relationship, it is possible to identify whether a cell is an odd-numbered cell or even-numbered cell among the cells collectively selected by a gate line GL at a height in the z axis direction as mentioned above.

One may think that since the lines of the gate polysilicon layer 21p are eventually all short-circuited, it is simpler to short-circuit all the lines to form the polysilicon layer, whether they are odd-numbered or even-numbered, than to short-circuit the odd-numbered group and the even-numbered group independently of each other and then short-circuit them through the contact GC1 and gate line GL1. However, by short-circuiting the odd-numbered group and the even-numbered group independently of each other and short-circuiting them through a contact and a gate line as mentioned above, the gate polysilicon layer 21p (and 22p, 23p, and 24p) can have the same shape as 81p. As a consequence, all these gate polysilicon layers can be made using the same mask, leading to a substantial reduction in the manufacturing cost.

FIG. 6 is an enlarged view of the memory array MA part shown in FIG. 5. Polysilicon diodes PD are formed at intervals on plural word lines 2 in the word line extending direction. The gate polysilicon layers 21p, 22p, 23p, 24p, and 81p and the insulating film layers 11, 12, 13, 14, 15, and 71 constitute a laminated film which is stripe-patterned parallel to the word line extending direction. This pattern consists of line portions and space portions, in which during the manufacturing process, the laminated film (comprised of the gate polysilicon layers 21p, 22p, 23p, 24p, and 81p and insulating film layers 11, 12, 13, 14, 15, and 71) is left in the line portions and removed in the space portions.

In the laminated film comprised of the gate polysilicon layers 21p, 22p, 23p, 24p, and 81p and insulating film layers 11, 12, 13, 14, 15, and 71, the line portions of the stripe pattern lie just above the spaces between word lines and the space portions lie just above the word lines. The bit lines 3 extend perpendicularly to the word lines, forming a stripe pattern and lie over the insulating film 71 with the n-type polysilicon layer 38p between them.

Under the bit lines 3 in the space portions of the laminated film comprised of the gate polysilicon layers 21p, 22p, 23p, 24p, and 81p and insulating film layers 11, 12, 13, 14, 15, and 71, the gate insulating film 9, channel polysilicon layer 8p, insulating film layer 10, and phase-change material layer 7 are stacked in order on the sidewalls of the gate polysilicon layers 21p, 22p, 23p, 24p, and 81p and the sidewalls of the insulating film layers 11, 12, 13, and 14 and the lower part of the sidewall of the insulating film 15. The insulating film layer 10 is intended to prevent diffusion between the phase-change material layer 7 and channel polysilicon layer 8p. An insulating film layer 91 is embedded between the phase-change material layers 7 on both sides. The gate insulating film layer 9 and channel polysilicon layer 8p are laminated on the upper part of the sidewall of the insulating film layer 15 and the sidewalls of the gate polysilicon layer 81p and insulating film layer 71. An insulating film layer 91 is embedded between the phase-change material layers on both sides. The gate insulating film layer 9 and channel polysilicon layer 8p are stacked on the upper part of the sidewall of the insulating film layer 15 and the sidewalls of the gate polysilicon layer 81p and insulating film layer 71. An insulating film layer 92 is embedded between the insulating film layers 71 on both sides. At the bottom of the area under the bit lines 3 in the space portions of the laminated film comprised of the gate polysilicon layers 21p, 22p, 23p, 24p, and 81p and insulating film layers 11, 12, 13, 14, 15, and 71, the upper surface of the polysilicon layer 62p is in contact with the channel polysilicon layer 8p. The bit lines 3 and the polysilicon diode PD are connected through the polysilicon layer 38p and channel polysilicon layer 8p on both the lateral sides of the laminated film comprised of the gate polysilicon layers 21p, 22p, 23p, 24p, and 81p and insulating film layers 11, 12, 13, 14, 15, and 71.

Under the space portions of the laminated film comprised of the gate polysilicon layers 21p, 22p, 23p, 24p, and 81p and insulating film layers 11, 12, 13, 14, 15, and 71 and under the space portions of the stripe pattern of the bit lines 3, the channel polysilicon layer 8p, phase-change material layer 7 and insulating film layer 10 are removed, forming space portions of the polysilicon diode PD pattern over the word lines 2. Though not shown in FIG. 6 for illustration simplicity, insulating film 32 is embedded in these space portions.

The semiconductor memory device according to the present invention stores data by taking advantage of the fact that the resistance of the phase-change material contained in the phase-change material layer 7 such as Ge₂Sb₂Te₅ is different between its amorphous state and crystalline state. The resistance is high in the amorphous state and low in the crystalline state. Thus, reading is done by giving a potential difference to both ends of the resistance-change element and measuring the current flowing in the element to decide whether the resistance is high or low.

FIG. 7 is a graph showing change in the temperature of the recording layer in writing operation of the phase-change random access memory according to the first embodiment of the invention. Setting, or operation to change the phase-change material from the amorphous state (high resistance) to the crystalline state (low resistance), and resetting, or operation to change it from the crystalline state to the amorphous state, are performed by enabling the temperature of the phase-change material to change as shown in FIG. 7. Specifically, the phase-change material in the amorphous state can be crystallized by heating it to the crystallization temperature or more and holding it as it is for 10⁻⁶ seconds or more. Also, the crystallized phase-change material can be turned into the amorphous state by heating it to the melting temperature or more to liquefy it and then cooling it rapidly.

FIG. 8 shows a portion of the memory cell array MA according to the first embodiment. The figure also includes a top view of the gate polysilicon layer 21p and a diagram of its equivalent circuit. The insulating film layer 31, which is omitted in FIGS. 5 and 6 for illustration simplicity, is embedded in the space between photodiodes PD.

For example, the following actions take place in a chain cell, namely a cell in which memory cells, including transistors and phase-change elements connected in parallel as mentioned above, are connected in series (in the explanation below, when “0 V” is given as a voltage value, it means that 0 V is applied for any of resetting, setting, and reading operations unless otherwise specified). 0 V is applied to the gate line GL1 connected with the selection cell SMC to turn off the transistor which uses the channel polysilicon layer 8p as a channel. 5 V is applied to the gate lines GL2, GL3, and GL5 which are not connected with the selection cell SMC to turn on the transistors. 0 V is applied to the bit line BL1 and 4 V, 3 V, and 2 V are applied to the word line WL1 for resetting, setting and reading operations respectively. As for the gate polysilicon of the selection transistor, 5 V is applied to the gate connected with SMC, namely STGL1, to turn on the transistor. 0 V is applied to the gate not connected with SMC, namely STGL2, to turn off the transistor. In each non-selection cell USMC1, with the transistor on, the channel resistance is low and the resistance of the channel polysilicon layer 8p of STGL1 (which is on) is low. Virtually the same current can flow regardless of the state of the phase-change material layer 7 in USMC1. In SMC, the transistor is off, so current flows in the phase-change material layer 7. For resetting or setting operation, the resistance of the phase-change material 7 changes depending on the current flowing in the phase-change material layer 7. For reading operation, SMC determines the current flowing in the phase-change material layer 7. Since the transistors of the non-selection cell USMC2 and non-selection cell USMC3 share gate voltages with the transistors of SMC and USMC1 respectively, the transistor of USMC2 is off and the transistor of USMC3 is on. Since the selection transistor with STGL2 connected with the gate polysilicon layer 81p is off, no current flows through USMC2 and USMC3. Therefore, only in SMC, current flows in the phase-change material layer 7 permitting selective operation. As an illustration of the phase-change element as seen from above, a sectional view of the vertical chain memory as taken horizontally is given in FIG. 8.

FIG. 9 shows the voltages of the bit lines BL1, BL2, BL3, and BL4 and the word lines WL1, WL2, and WL3, the gate wires GL1, GL2, GL3, and GL4, and the gate wires STGL1 and STGL2 in resetting, setting and reading operations.

As in the case of FIG. 8, the voltages of WL1, 4/3/2 V, indicate the voltages for resetting, setting, and reading operations respectively. Similarly the expressions of voltages of other terminals in FIG. 9 indicate the voltages for resetting, setting, and reading operations in order. When the vertical chain memory is connected with bit line BL2, BL3 or BL4 and word line WL1, the voltages of the bit line and word line are both 4 V in resetting operation, both 3 V in setting operation, and both 2 V in reading operation, so there is no potential difference and thus no current flows. When the vertical chain memory is connected with bit line BL1 and word line WL2 or WL3, the voltages of the bit line and word line are both 0 V in resetting operation, setting operation and reading operation, so there is no potential difference and thus no current flows. When the vertical chain memory is connected with bit line BL2, BL3 or BL4 and word line WL2 or WL3, 0 V and 4 V are applied to the word line and bit line in resetting operation respectively and 0 V and 3 V are applied to the word line and bit line in setting operation respectively, and 0 V and 2 V are applied to the word line and bit line in reading operation respectively. The voltage is applied in the reverse bias direction of the polysilicon diode PD which selects the vertical chain memory. It is possible to design the device so that the off-state current in the reverse bias direction of the polysilicon diode PD is sufficiently lowered.

It is possible to design the device so that only in the vertical chain memory connected with bit line BL1 and world line WL1, a forward bias voltage is applied to the PD to apply a current. SMC in the vertical chain can be selected and activated with the procedure described in reference to FIG. 8, which means that SMC in the memory array can be selected and activated.

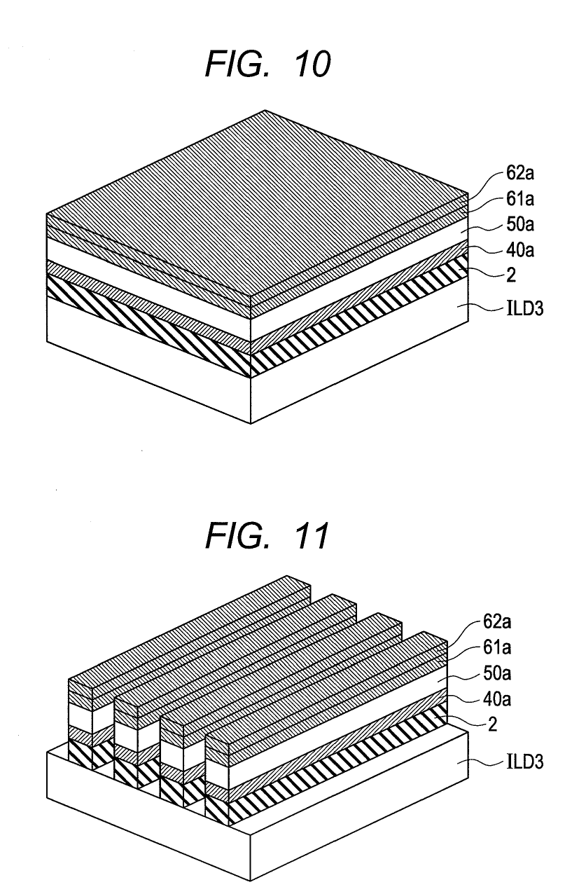

Next, the method for manufacturing a semiconductor memory device according to the first embodiment of the invention will be described, referring to FIGS. 10 to 29.

As shown in FIG. 10, an interlayer insulating film ILD3, a tungsten film layer 2 for word lines, an amorphous silicon layer 40a doped with p-type impurities, an amorphous silicon layer 50a doped with a low concentration of impurities, an amorphous silicon layer 61a doped with n-type impurities, and an amorphous silicon layer 62a doped with n-type impurities are deposited in order on a semiconductor substrate 1 where a peripheral circuit and word line contacts WLC are formed.

The method for manufacturing a semiconductor memory device according to the first embodiment is thus characterized in that the process for the formation of a third diode semiconductor layer includes the steps of stacking more than one semiconductor layer of the second conductivity type (for example, n type) as a means to annihilate carriers of the first conductivity type (for example, p type). The effect of such means is as discussed above.

Then, as shown in FIG. 11, the deposited films are shaped into a stripe pattern extending in the direction of word lines. At this time, the amorphous silicon layers 40a, 50a, 61a, and 62a and the word line layer are collectively processed in a self-aligning manner, thereby preventing misalignment between the word line layer and each layer of the amorphous silicon pillar and eventually improving the reliability of rewriting operation of the memory.

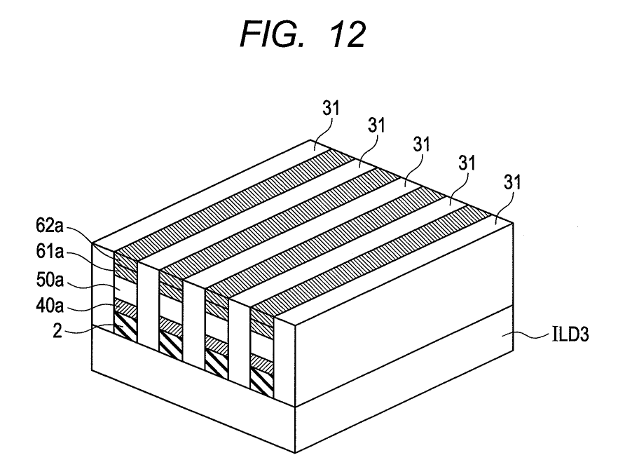

Then, the space portions shown in FIG. 11 are filled with insulating film 31 and the upper part of the insulating film 31 is removed and flattened by chemical mechanical polishing so as to expose the upper surface of the amorphous silicon layer 62a as shown in FIG. 12.

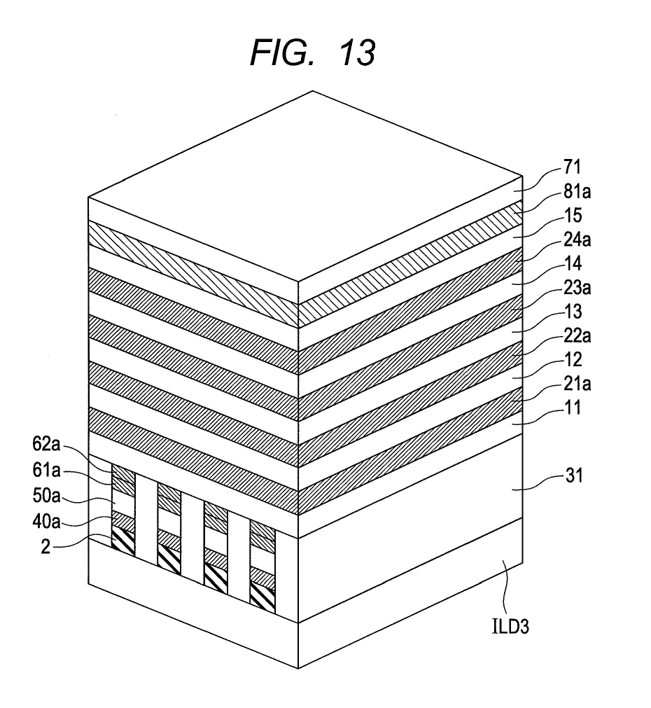

Then, as shown in FIG. 13, an insulating film layer 11, an amorphous silicon layer 21a, an insulating film layer 12, an amorphous silicon layer 22a, an insulating film layer 13, an amorphous silicon layer 23a, an insulating film layer 14, an amorphous silicon layer 24a, an insulating film layer 15, an amorphous silicon layer 81a, and an insulating film layer 71 are deposited in order. The amorphous silicon layers 21a to 24a and 81a are doped with phosphorous (P).

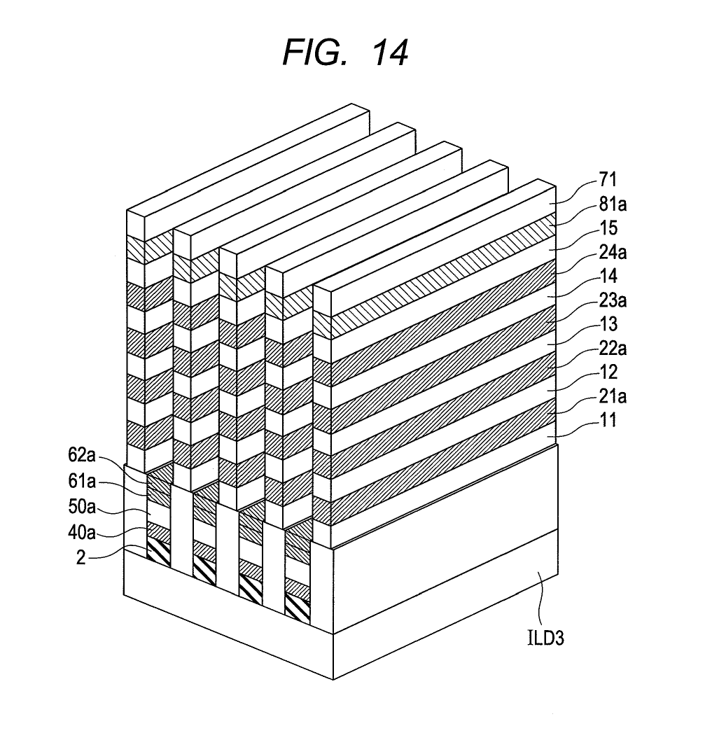

Next, the laminated film produced as shown in FIG. 13 is shaped into stripes parallel to the direction in which the word lines 2 extend (FIG. 14). This process is carried out in a way that the space portions of the stripe pattern of the laminated film, comprised of the insulating film layer 11, amorphous silicon layer 21a, insulating film layer 12, amorphous silicon layer 22a, insulating film layer 13, amorphous silicon layer 23a, insulating film layer 14, amorphous silicon layer 24a, insulating film layer 15, amorphous silicon layer 81a, and insulating film layer 71, are located just above the word lines 2.

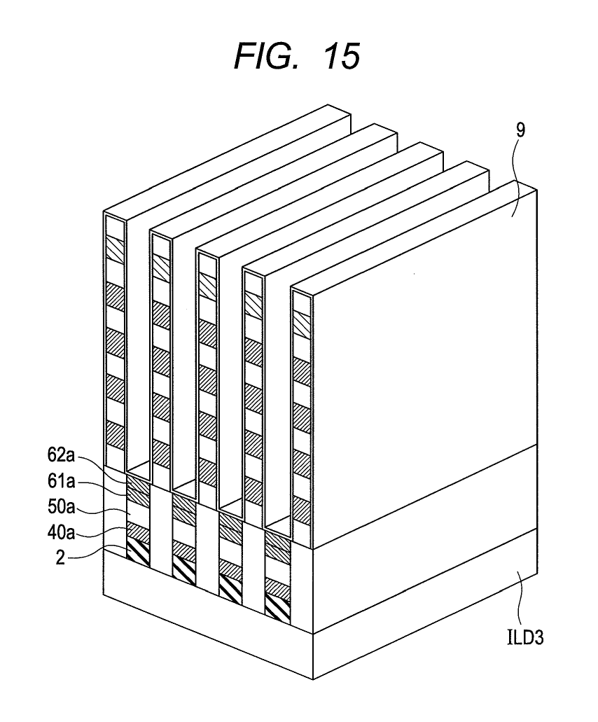

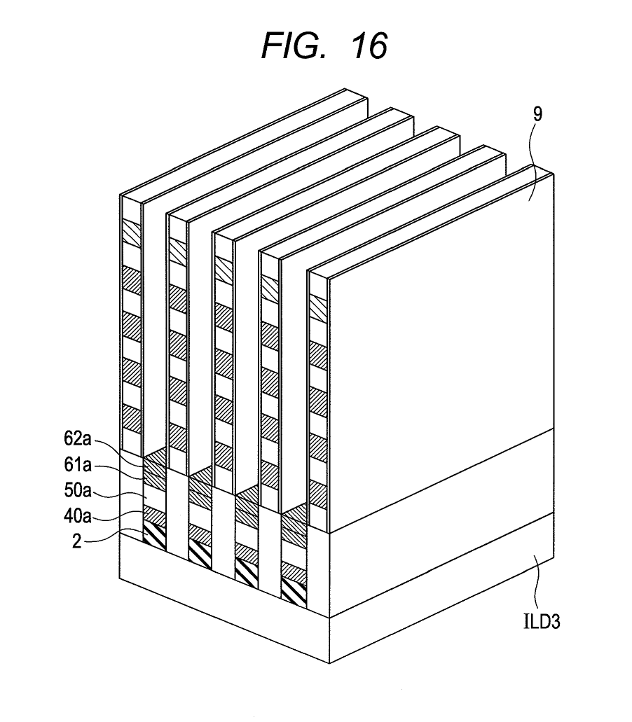

Then, as shown in FIG. 15, an insulating film 9 is deposited in a way not to completely fill the space portions produced as shown in FIG. 14.

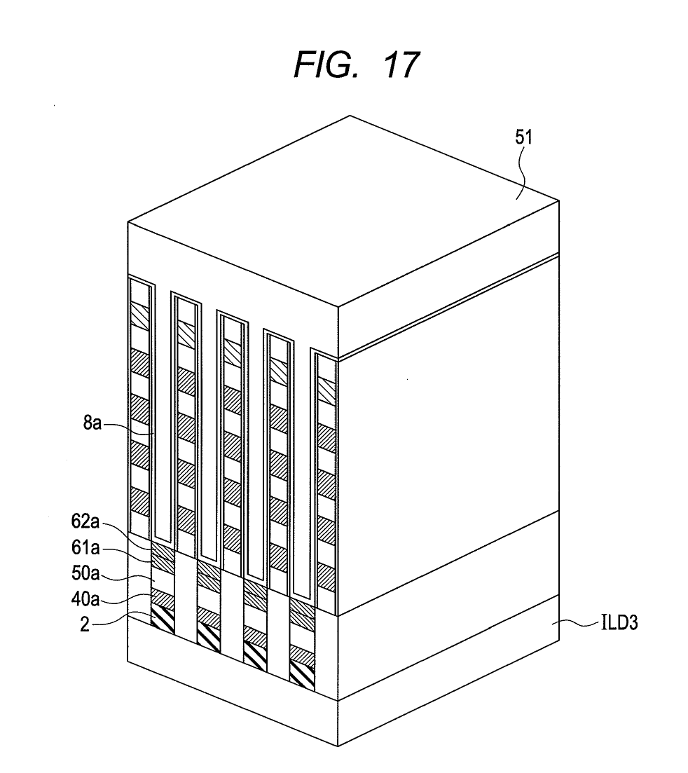

Then, as shown in FIG. 16, the insulating film on the top surface and amorphous silicon 62a is etched back and removed.

Then, an amorphous silicon layer 8a is deposited in a way not to fill the space portions shown in FIG. 16 completely and an insulating film 51 is further deposited in a way to fill the space portions completely (FIG. 17).

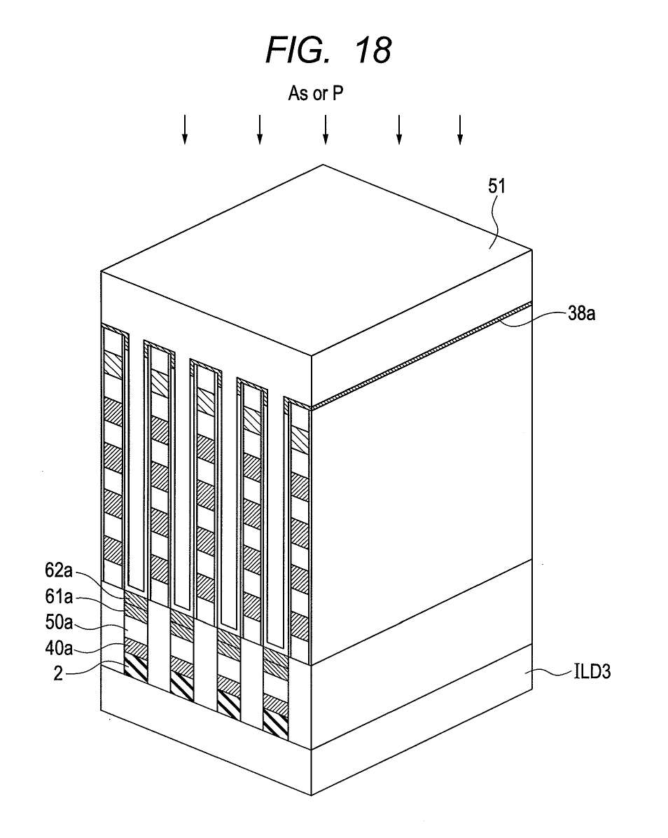

Then, the upper parts of the amorphous silicon layer 8a are doped with impurities of the same conductivity type as the amorphous silicon layers 61a and 62a, such as arsenic (As) or phosphorous (P) by ion implantation. The doped amorphous silicon 8a turns into amorphous silicon 38a (FIG. 18).

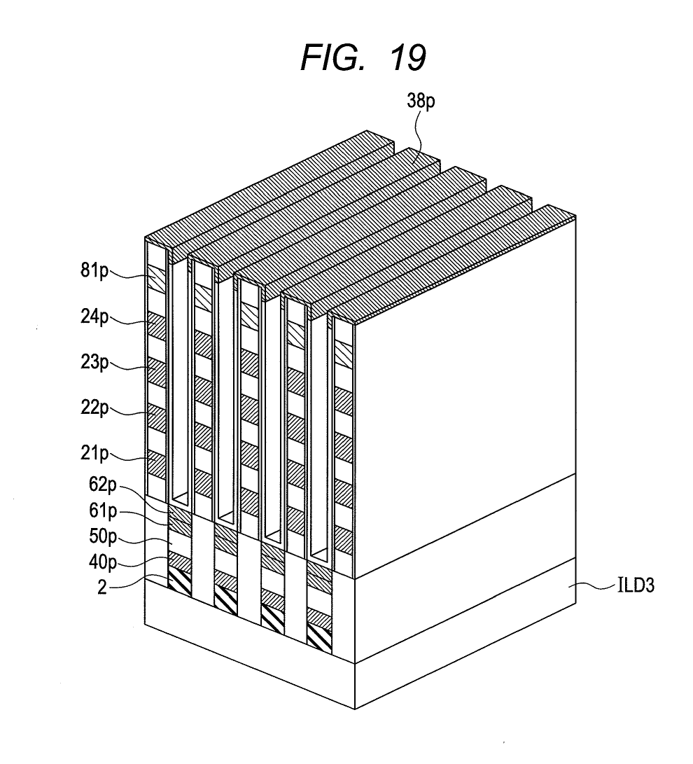

Then, after heat treatment is carried out to crystallize the amorphous silicon layers 40a, 50a, 61a, 62a, 8a, 21a, 22a, 23a, 24a, 25a, and 81a and activate the impurities contained in these layers, the insulating film 51 is removed, for example, by wet etching. The heat-treated amorphous silicon layers 40a, 50a, 61a, 62a, 8a, 21a, 22a, 23a, 24a, 25a, and 81a turn into polysilicon layers 40p, 50p, 61p, 62p, 8p, 21p, 22p, 23p, 24p, and 81p respectively as shown in FIG. 19.

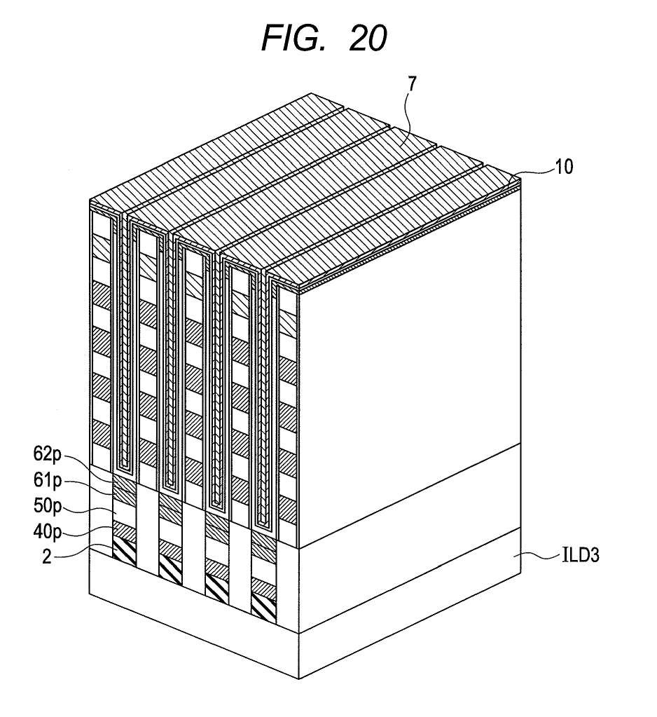

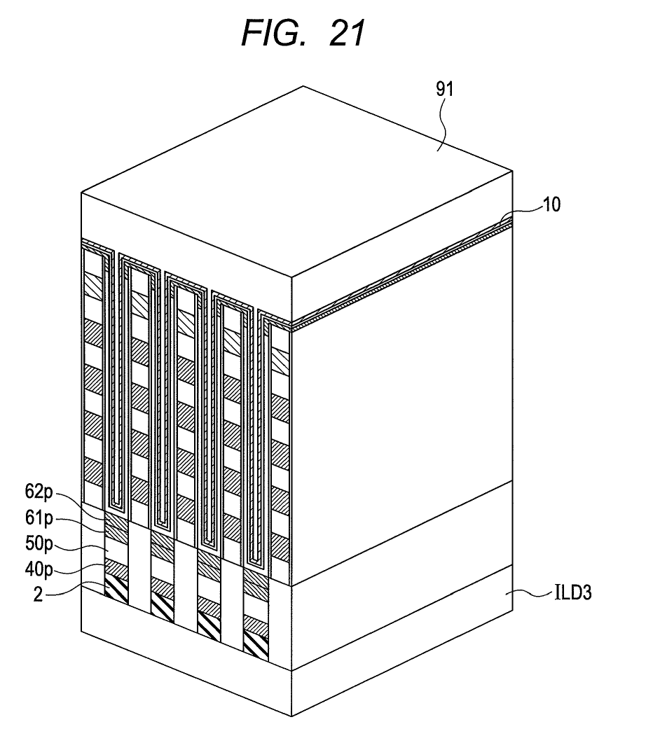

Then, as shown in FIG. 20, an insulating film layer 10 and a phase-change material layer 7 are deposited in a way not to fill the space portions completely; then as shown in FIG. 21, an insulating film layer 91 is deposited in a way to fill the space portions completely.

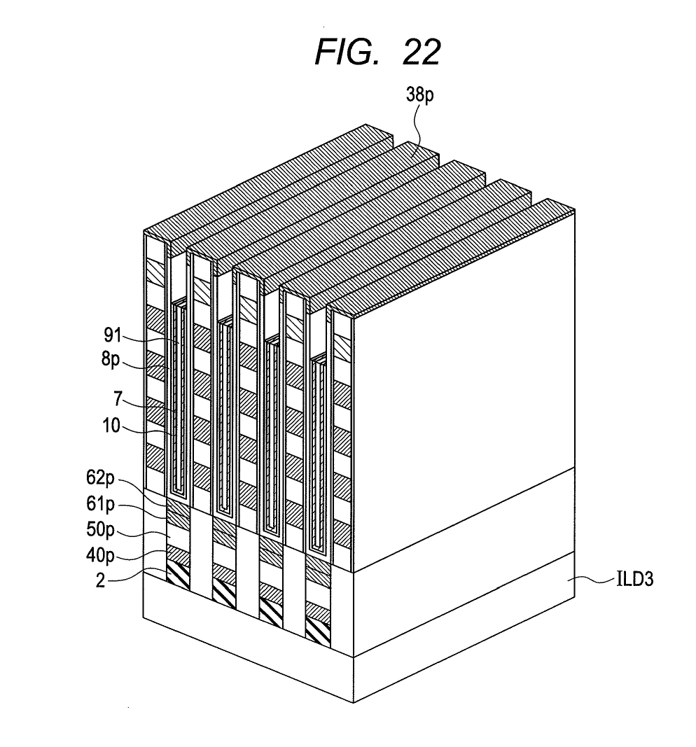

Then, as shown in FIG. 22, etching back is done so that the top surface of the phase-change material layer 7 is below the top of the insulating film layer 15 and above the bottom of the insulating film layer 15. The purpose of making the top surface of the phase-change material layer 7 below the top of the insulating film layer 15 is to prevent current from flowing through the phase-change material layer 7 to the source/drain when the gate of the gate polysilicon layer 81p turns off. Also, the purpose of making it above the bottom of the insulating film layer 15 is to enable current to flow through the phase-change material layer 7 to the source/drain when the gate of the polysilicon 24p formed just below the insulating film layer 15 turns off. At the same time, the insulating film layer 91 is partially removed.

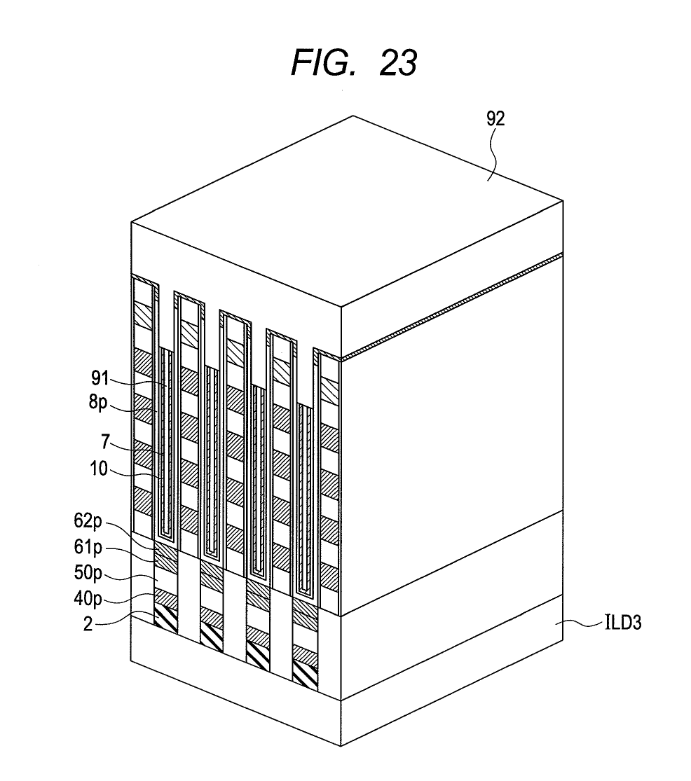

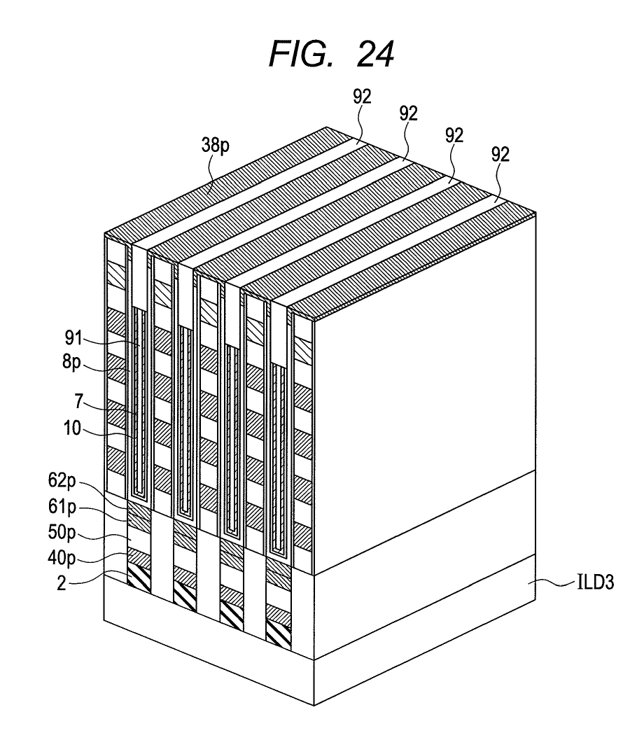

Then, the space portions are filled with an insulating film layer 92 as shown in FIG. 23 and the top surface of the polysilicon layer 38p is exposed by etching back as shown in FIG. 24.

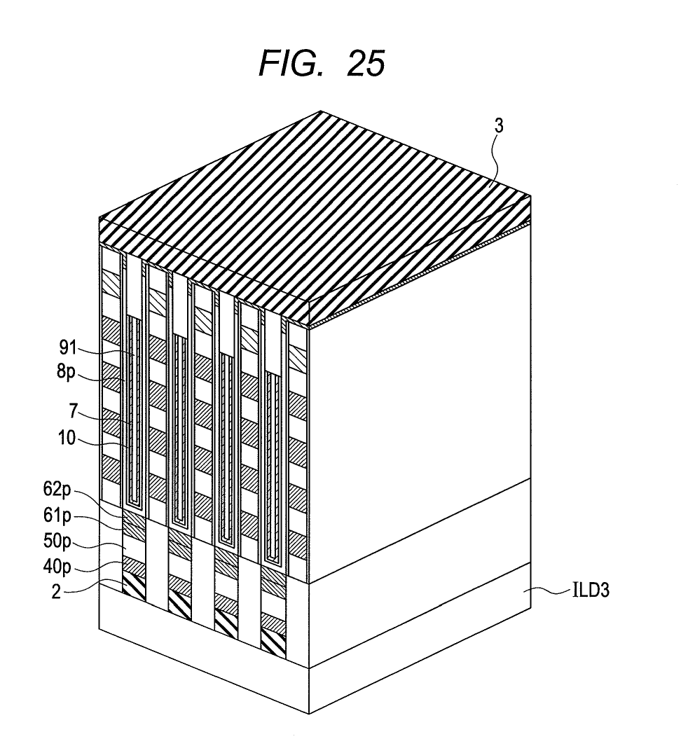

Then, contacts BLC for connecting the bit lines 3 and the peripheral circuit formed on the semiconductor substrate are made as shown in FIGS. 4 and 5. After that, the material for the bit lines 3 is deposited as shown in FIG. 25.

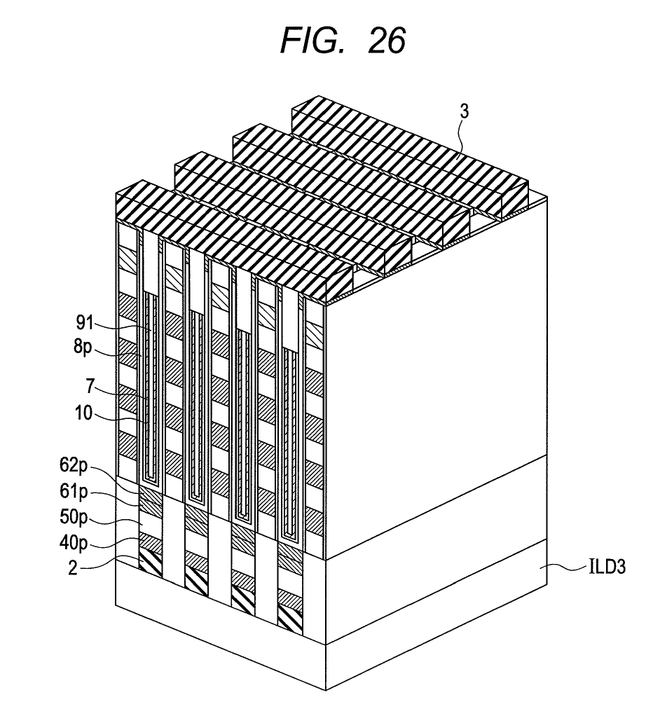

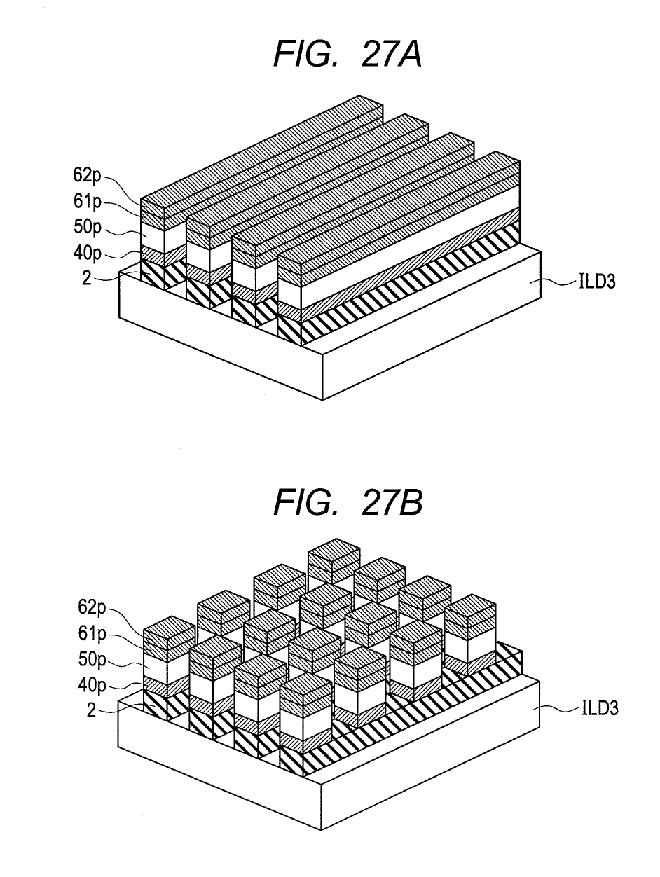

Then, the material to be shaped into bit lines 3, the n-type polysilicon layer 38p, insulating film layer 92, channel polysilicon layer 8p, insulating film layer 10, phase-change material layer 7, insulating film layer 91, and polysilicon layers 62p, 61p, 50p, and 40p are shaped into a stripe pattern extending vertically to the word lines 2. When making a stripe pattern of bit lines 3, the corresponding parts of the laminated film (comprised of the gate polysilicon layers 21p, 22p, 23p, 24p, and 81p and insulating film layers 11, 12, 13, 14, 15, and 71) and the gate insulating film layer 9 remain unprocessed while the corresponding parts of the channel polysilicon layer 8p, polysilicon layer 38p, phase-change material layer 7 and insulating film layer 10 are removed (FIG. 26). In addition, the corresponding parts of the polysilicon diode PD over the word lines 2 are removed all at once according to the above stripe patterning. At the step of FIG. 25, the polysilicon layers 40p, 50p, 61p, and 62p are shaped into a stripe pattern extending in the direction of word lines 2 as shown in FIG. 27A and at the step of FIG. 26, they are so shaped that they are left only in the intersections of the word lines and bit lines as shown in FIG. 27B.

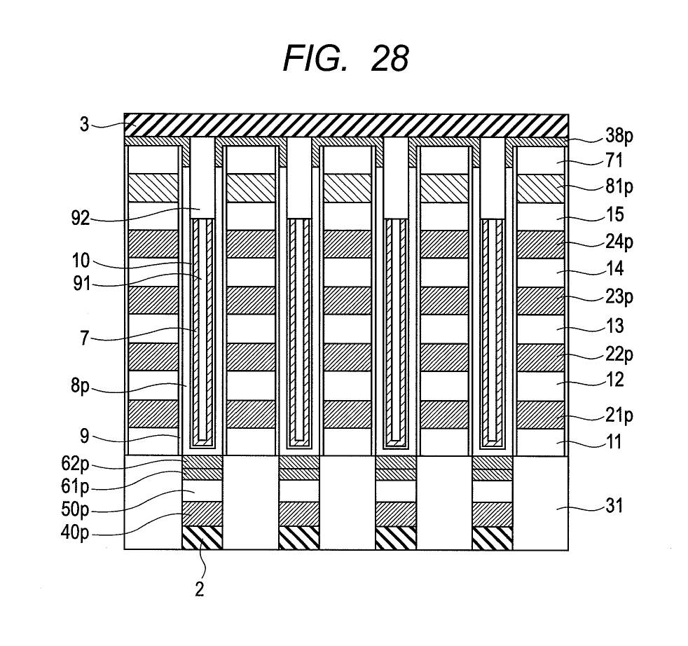

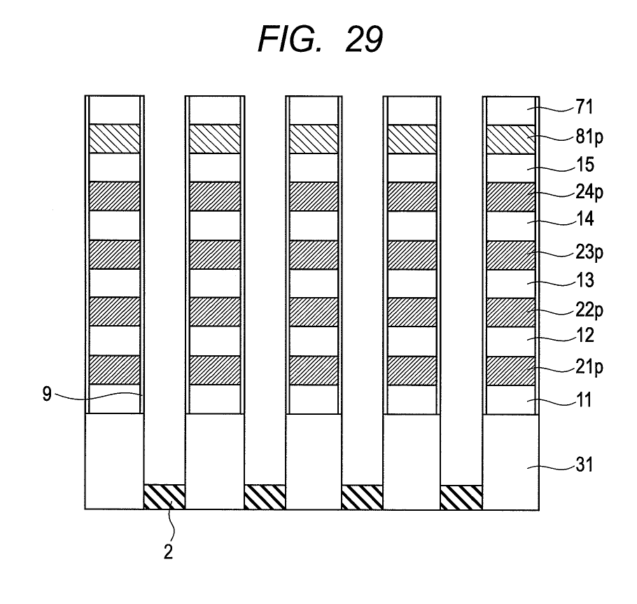

FIG. 28 is a sectional view of a bit line portion shown in FIG. 26 and FIG. 29 is a sectional view of a space portion shown in FIG. 26.

After that, the gate polysilicon at the memory array end is processed so as to form contacts for the layers as shown in FIG. 5 and the whole laminate including the stripe-patterned layers is filled with interlayer insulating film. Contacts GC1, GC2, GC3, and GC4 leading to the gate polysilicon layers 21p, 22p, 23p, and 24p respectively, contacts STGC1 and STGC2 leading to the gate polysilicon layer 61p, gate wires GL1, GL2, GL3, GL4, STGL1, and STGL2, and contacts GLC1, GLC2, GLC3, GLC4, STGLC1, and STGLC2 for connecting the gate wires and the peripheral circuit are formed to constitute the semiconductor memory device.

In short, the method for manufacturing a semiconductor device according to the first embodiment is characterized by including the following steps: forming first selection lines on a semiconductor substrate; forming a first diode semiconductor layer of the first conductivity type on the first selection lines; forming a second diode semiconductor layer of the second conductivity type on the first semiconductor layer; making a means to annihilate carriers of the first conductivity type over the first diode semiconductor layer; forming plural gate semiconductor layers stacked through plural insulating layers over the semiconductor substrate; forming a gate insulating layer along the lateral sides of the gate semiconductor layers; and forming a channel layer along the lateral side of the gate insulating layer where the gate semiconductor layers are not provided.

The drawings which illustrate the first embodiment show that the polysilicon diode PD is comprised of two n-type polysilicon layers 61p and 62p; however, it may be comprised of three or more such layers.

The drawings which illustrate the first embodiment show that four gate polysilicon layers are stacked for a memory cell; however, five or more such layers may be stacked.

Thus the semiconductor memory device according to the first embodiment is summarized as follows. When a forward bias voltage is applied to the diode PD to apply a current, holes from the p-type polysilicon layer 40p are trapped in the boundary between the n-type polysilicon layers 61p and 62p, combined with electrons and annihilated so that diffusion of holes into the channel polysilicon 8p is reduced. Since minority carriers are combined with majority carriers and annihilated in the boundary between semiconductor layers and minority carriers do not diffuse to the cell transistor side, reading, setting or resetting errors as caused by a failure to turn off the cell transistor normally are less likely to occur in the semiconductor memory device, improving the reliability of the device.

### Second Embodiment

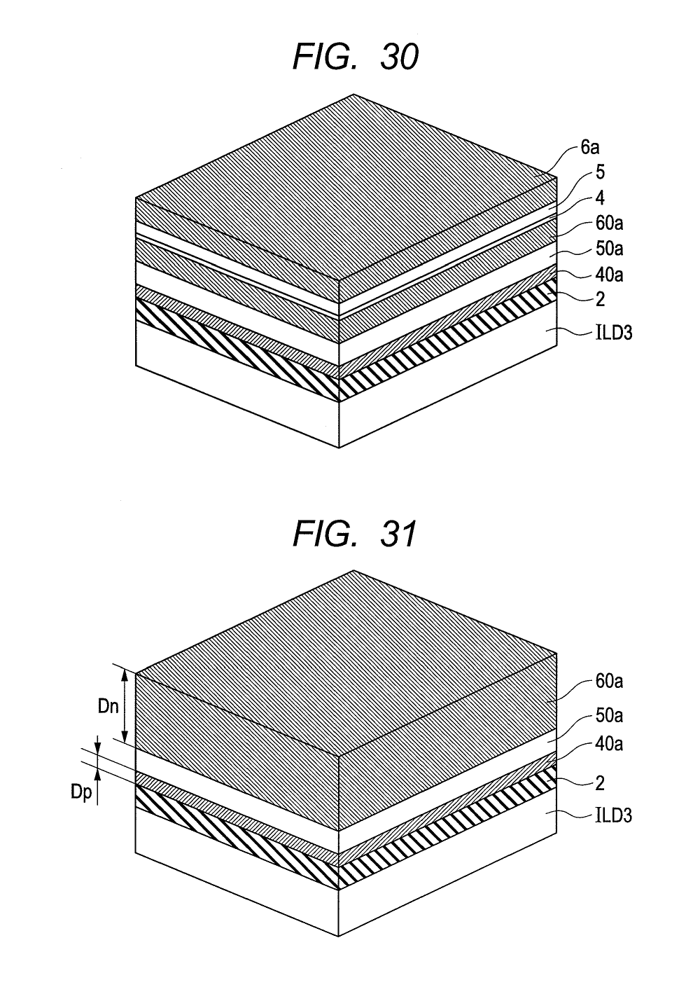

While in the first embodiment the n-type polysilicon layer is formed between the polysilicon diode PD and vertical transistor, in the second embodiment a metal film layer is inserted between the polysilicon diode PD (where carriers are generated) and vertical transistor as a means to annihilate carriers or make the current flowing from the diode PD to the channel layer not more than one hundredth of the current flowing in the diode. As at the step shown in FIG. 10 in the first embodiment, an interlayer insulating film ILD3, a tungsten film layer 2 for word lines, an amorphous silicon layer 40a doped with p-type impurities, an amorphous silicon layer 50a doped with a low concentration of impurities, an amorphous silicon layer 60a doped with n-type impurities, a titanium (Ti) film 4, a titanium nitride (TiN) film 5, and an amorphous silicon layer 6a doped with n-type impurities are deposited in order on a semiconductor substrate 1 where a peripheral circuit and word line contacts WLC are formed (FIG. 30). After that, the memory cell is completed by taking the same steps as those shown in FIGS. 11 to 29 where the amorphous silicon layers 40a, 50a, 60a, and 6a are crystallized to turn into polysilicon 40p, 50p, 60p, and 6p respectively. The Ti film 4 and TiN film 5 lie between the polysilicon diode PD comprised of the polysilicon layers 40p, 50p, and 60p and the polysilicon layer 6p as the diffusion layer of the vertical transistor.

As mentioned above, the semiconductor memory device according to the second embodiment is characterized by having metal layers (Ti film 4 and TiN film 5) which are located between the third diode semiconductor layer and channel layer and electrically connected with them. In the second embodiment, when a forward bias voltage is applied to the diode PD to apply a current, holes from the p-type polysilicon layer 40p are combined with electrons and annihilated in the Ti film 4 and TiN film 5 between the n-type polysilicon layers 60p and 6p so that diffusion of holes into the channel polysilicon 8p is reduced. This reduces the possibility of reading, setting or resetting errors in the semiconductor memory device as caused by a failure to turn off the cell transistor normally and improves the reliability of the device.

### Third Embodiment

In the third embodiment, the thickness of the n-type polysilicon layer 60p where the polysilicon diode PD contacts the vertical transistor is increased as a means to annihilate carriers between the channel layer and the semiconductor layer of the diode PD where carriers are generated or to make the current flowing from the diode PD to the channel layer not more than one hundredth of the current flowing in the diode.

As at the step shown in FIG. 10 in the first embodiment, an interlayer insulating film ILD3, a tungsten film layer 2 for word lines, an amorphous silicon layer 40a doped with p-type impurities, an amorphous silicon layer 50a doped with a low concentration of impurities, and an amorphous silicon layer 60a doped with n-type impurities are deposited in order on a semiconductor substrate 1 where a peripheral circuit and word line contacts WLC are formed (FIG. 31). As shown in FIG. 31, the thickness Dn of the layer 60a should be larger than the thickness Dp of the p-type silicon layer 40a. After that, the memory cell is completed by taking the same steps as those shown in FIGS. 11 to 29 where the amorphous silicon layers 40a, 50a, and 60a are crystallized to turn into polysilicon 40p, 50p, and 60p respectively.

In the third embodiment, when a forward bias voltage is applied to the diode PD to apply a current, holes are combined with electrons and annihilated in the thick n-type polysilicon layer 60p so that diffusion of holes into the channel polysilicon 8p is reduced. This reduces the possibility of reading, setting or resetting errors in the semiconductor memory device as caused by a failure to turn off the cell transistor normally and improves the reliability of the device.

### Fourth Embodiment

While in the third embodiment the thickness of the n-type polysilicon layer 60p where the polysilicon diode PD contacts the vertical transistor is increased, in the fourth embodiment the impurity concentration of the layer 60p is increased in order to annihilate carriers between the channel layer and the semiconductor layer of the diode PD where carriers are generated or to make the current flowing from the diode PD to the channel layer not more than one hundredth of the current flowing in the diode. In the fourth embodiment, as at the step shown in FIG. 31, an interlayer insulating film ILD3, a tungsten film layer 2 for word lines, an amorphous silicon layer 40a doped with p-type impurities, an amorphous silicon layer 50a doped with a low concentration of impurities, and an amorphous silicon layer 60a doped with n-type impurities are deposited in order on a semiconductor substrate 1 where a peripheral circuit and word line contacts WLC are formed. In this process, doping is done so that the impurity concentration of the layer 60a is higher than that of the p-type silicon layer 40a. After that, the memory cell is completed by taking the same steps as those shown in FIGS. 11 to 29 where the amorphous silicon layers 40a, 50a, and 60a are crystallized to turn into polysilicon 40p, 50p, and 60p respectively.

In the fourth embodiment, when a forward bias voltage is applied to the diode PD to apply a current, holes from the p-type polysilicon layer 40p are combined with electrons and annihilated in the n-type polysilicon layer 60p where the electron concentration is high due to its high impurity concentration, so that diffusion of holes into the channel polysilicon 8p is reduced. This reduces the possibility of reading, setting or resetting errors in the semiconductor memory device as caused by a failure to turn off the cell transistor normally and improves the reliability of the device.

### Fifth Embodiment

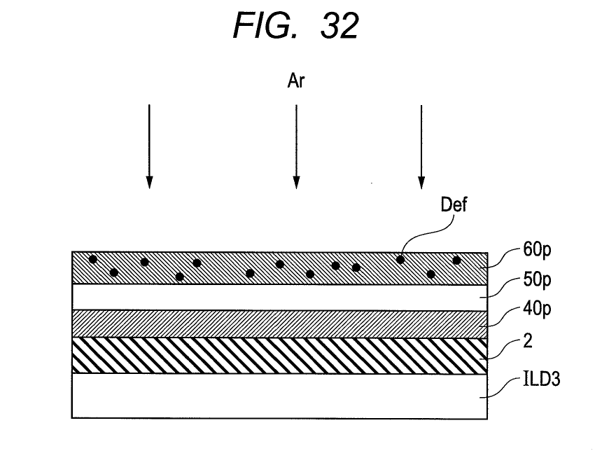

In the fifth embodiment, the n-type polysilicon layer 60p, where the polysilicon diode PD contacts the vertical transistor, is formed with a high concentration of crystal defects Def in order to annihilate carriers between the channel layer and the semiconductor layer of the diode PD where carriers are generated or to make the current flowing from the diode PD to the channel layer not more than one hundredth of the current flowing in the diode. After the step shown in FIG. 10 in the first embodiment, the amorphous silicon layers 40a, 50a, and 60a are crystallized to turn into polysilicon 40p, 50p, and 60p respectively. After that, as shown in FIG. 31, for example, argon (Ar) ions as inactive impurities are implanted only into the n-type polysilicon layer 60p (FIG. 31). By doing so, high concentration crystal defects are generated only in the n-type polysilicon layer. In other words, the layer 60p is higher in terms of crystal defect concentration than the layers 40p and 50p (FIG. 32). After that, the memory cell is completed by taking the same steps as those shown in FIGS. 11 to 29.

In the fifth embodiment, when a forward bias voltage is applied to the diode PD to apply a current, holes from the p-type polysilicon layer 40p are trapped by a high concentration of crystal defects in the n-type polysilicon layer 60p and combined with electrons and annihilated so that diffusion of holes into the channel polysilicon 8p is reduced. This reduces the possibility of reading, setting or resetting errors in the semiconductor memory device as caused by a failure to turn off the cell transistor normally and improves the reliability of the device.

### Sixth Embodiment

In the first to fifth embodiments, a chain memory which uses a phase-change random access memory is formed over the polysilicon diode PD. However, it is also possible to use a discrete trap film (charge storage film) for the gate insulating film of the vertical transistor to make a flash memory.

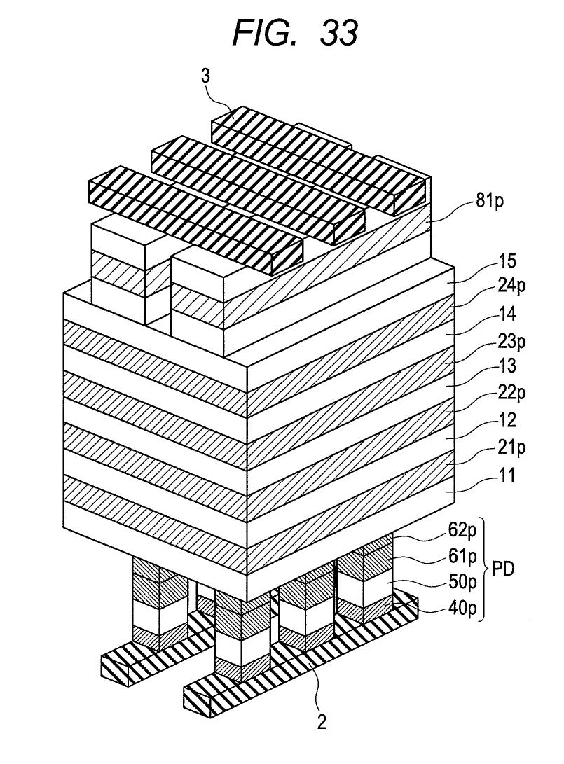

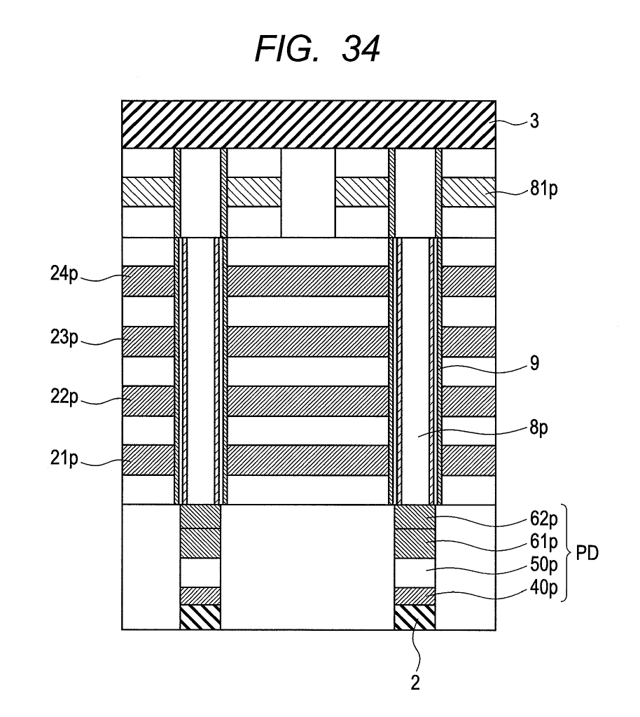

FIG. 33 is a schematic perspective view showing the semiconductor memory device according to the sixth embodiment and FIG. 34 is a sectional view taken along a bit line 3. The diode is divided for each group of cells connected in series vertically. Although FIGS. 33 and 34 show electrode wires 2 at the bottom to form a stripe pattern perpendicular to the bit lines 3, instead of the electrode wires 2 a single plate may be used at the bottom for the flash memory in the sixth embodiment.

In the sixth embodiment, when a forward bias voltage is applied to the diode PD to apply a current, holes from the p-type polysilicon layer 40p are combined with electrons and annihilated so that diffusion of holes into the channel polysilicon 8p is reduced. This reduces the possibility of reading, setting or resetting errors in the semiconductor memory device as caused by a failure to turn off the cell transistor off normally and improves the reliability of the device.

1. A semiconductor memory device comprising:
a first selection line provided over a semiconductor substrate;
a first diode semiconductor layer which is electrically connected with the first selection line and is of first conductivity type;
a second diode semiconductor layer which is electrically connected with the first diode semiconductor layer and is of second conductivity type different from the first conductivity type;
a plurality of gate semiconductor layers stacked through a plurality of insulating layers over the semiconductor substrate;
a gate insulating film layer provided along lateral sides of the gate semiconductor layers;
a channel layer which is provided on a lateral side of the gate insulating film layer where the gate semiconductor layers are not provided and is electrically connected with the second diode semiconductor layer; and
a second selection line which is electrically connected with the channel layer and extends perpendicularly to the first selection line,
wherein a structure to annihilate carriers of the first conductivity type is positioned between the first diode semiconductor layer and the channel layer.

2. The semiconductor memory device according to claim 1, further comprising:
a third diode semiconductor layer which is provided between the first diode semiconductor layer and the second diode semiconductor layer and is electrically connected with the first diode semiconductor layer and the second diode semiconductor layer,
wherein an impurity concentration of the third diode semiconductor layer is lower than an impurity concentration of the first diode semiconductor layer and an impurity concentration of the second diode semiconductor layer.

3. The semiconductor memory device according to claim 1, further comprising:
a resistance-change material layer which is provided along a lateral side of the gate insulating film layer where the gate semiconductor layers are not provided, and is electrically connected with the second diode semiconductor layer and the second selection line, and includes a material whose resistance changes depending on current flowing therein.

4. The semiconductor memory device according to claim 1, wherein the second diode semiconductor layer is a laminated structure including a plurality of semiconductor layers of the second conductivity type.

5. The semiconductor memory device according to claim 1, further comprising a metal layer which is provided between the second diode semiconductor layer and the channel layer and is electrically connected with the second diode semiconductor layer and the channel layer.

6. The semiconductor memory device according to claim 1, wherein a thickness of the second diode semiconductor layer is larger than a thickness of the first diode semiconductor layer in a direction vertical to a surface of the semiconductor substrate.

7. The semiconductor memory device according to claim 1, wherein an impurity concentration of the second diode semiconductor layer is higher than an impurity concentration of the first diode semiconductor layer.

8. The semiconductor memory device according to claim 1, wherein a lattice defect concentration of the second diode semiconductor layer is higher than a lattice defect concentration of the first diode semiconductor layer.

9. The semiconductor memory device according to claim 1, wherein the gate insulating film layer includes a charge storage film.

10. A semiconductor memory device comprising:
a first selection line provided over a semiconductor substrate;
a first diode semiconductor layer which is electrically connected with the first selection line and is of first conductivity type;
a second diode semiconductor layer which is electrically connected with the first diode semiconductor layer and is of second conductivity type different from the first conductivity type;
a plurality of gate semiconductor layers stacked through a plurality of insulating layers over the semiconductor substrate;
a gate insulating film layer provided along lateral sides of the gate semiconductor layers;
a channel layer which is provided on a lateral side of the gate insulating film layer where the gate semiconductor layers are not provided and is electrically connected with the second diode semiconductor layer; and
a second selection line which is electrically connected with the channel layer and extends perpendicularly to the first selection line,
wherein in operation, a current not more than one hundredth of a current flowing in a diode including the first diode semiconductor layer and the second diode semiconductor layer flows from the diode to the channel layer.

11. The semiconductor memory device according to claim 10, further comprising:
a third diode semiconductor layer which is provided between the first diode semiconductor layer and the second diode semiconductor layer and is electrically connected with the first diode semiconductor layer and the second diode semiconductor layer,
wherein an impurity concentration of the third diode semiconductor layer is lower than an impurity concentration of the first diode semiconductor layer and an impurity concentration of the second diode semiconductor layer.

12. The semiconductor memory device according to claim 10, further comprising:
a resistance-change material layer which is provided along a lateral side of the gate insulating film layer where the gate semiconductor layers are not provided, and is electrically connected with the second diode semiconductor layer and the second selection line, and includes a material whose resistance changes depending on current flowing therein.

13. The semiconductor memory device according to claim 10, wherein the gate insulating film layer includes a charge storage film.

14. A method for manufacturing a semiconductor memory device comprising the steps of:
forming a first selection line on a semiconductor substrate;
forming a first diode semiconductor layer of first conductivity type on the first selection line;
forming, over the first diode semiconductor layer, a second diode semiconductor layer of second conductivity type different from the first conductivity type;
forming, over the first diode semiconductor layer, a structure to annihilate carriers of the first conductivity type;
forming, over the semiconductor substrate, a plurality of gate semiconductor layers stacked through a plurality of insulating layers;
forming a gate insulating layer along lateral sides of the gate semiconductor layers; and
forming a channel layer along a lateral side of the gate insulating layer where the gate semiconductor layers are not provided.

15. The method for manufacturing a semiconductor memory device according to claim 14, further comprising the step of:
forming, on the first diode semiconductor layer, a third diode semiconductor layer with a lower impurity concentration than the first diode semiconductor layer and the second diode semiconductor layer before forming the second diode semiconductor layer.

16. The method for manufacturing a semiconductor memory device according to claim 14, further comprising the step of:
stacking a plurality of semiconductor layers of the second conductivity type when forming the second diode semiconductor layer.

17. The method for manufacturing a semiconductor memory device according to claim 14, further comprising the step of:
forming a metal layer on the second diode semiconductor layer.

18. The method for manufacturing a semiconductor memory device according to claim 14, wherein at the step of forming the second diode semiconductor layer, a thickness of the second diode semiconductor layer in a direction vertical to a surface of the semiconductor substrate is larger than a thickness of the first diode semiconductor layer.

19. The method for manufacturing a semiconductor memory device according to claim 14, wherein at the step of forming the second diode semiconductor layer, an impurity concentration of the second semiconductor layer is made higher than an impurity concentration of the first diode semiconductor layer.

20. The method for manufacturing a semiconductor memory device according to claim 14, further comprising the step of:
implanting inert element ions into the second diode semiconductor layer.
